(19) United States
(12) Patent Application Publication
(10) Pub. No.: US 2026/0077393 A1
(43) Pub. Date: Mar. 19, 2026

(54) SUBSTRATE PROCESSING APPARATUS AND SUBSTRATE PROCESSING METHOD

(71) Applicant: SEMES CO., LTD., Cheonan-si (KR)

(72) Inventors: Tae Keun KIM, Siheung-si (KR); Jun Hee CHOI, Yongin-si (KR); Kang Sul KIM, Hwaseong-si (KR); Kyeong Min LEE, Hwaseong-si (KR); Yong Jun KIM, Suwon-si (KR)

(73) Assignee: SEMES CO., LTD., Cheonan-si (KR)

(21) Appl. No.: 19/333,592

(22) Filed: Sep. 19, 2025

(30) Foreign Application Priority Data
Sep. 19, 2024 (KR) 10-2024-0126404

(51) Int. Cl. B08B 7/00; H01L 21/67

(52) U.S. Cl. CPC B08B 7/0014; H10P 72/0402

(57) ABSTRACT

Disclosed is a method of processing a substrate, the method including: a fluid supply operation of supplying fluid to a lower surface of a rotating substrate; a treatment solution supply operation of supplying a treatment solution containing a polymer and a volatile solvent to an upper surface of the rotating substrate; after the treatment solution supply operation, a liquid film forming operation of forming a liquid film of the treatment solution by volatilizing the volatile solvent in the treatment solution and solidifying or curing the treatment solution; and after the liquid film forming operation, a liquid film removing operation of removing the liquid film of the treatment solution by supplying a removal solution to the substrate, in which the fluid supply operation, the supply of the fluid starts before the liquid film forming operation.

### CROSS-REFERENCE TO RELATED APPLICATION

This application claims priority to and the benefit of Korean Patent Application No. 10-2024-0126404 filed in the Korean Intellectual Property Office on Sep. 19, 2024, the entire contents of which are incorporated herein by reference.

### TECHNICAL FIELD

The present invention relates to a substrate processing apparatus and a substrate processing method, and more particularly, to a substrate processing apparatus and a substrate processing method of cleaning a substrate.

### BACKGROUND ART

In general, various processes, such as photo process, etching process, ion implantation process, and deposition process, are performed to manufacture semiconductor devices. Further, before and after the processes are performed, a cleaning process for cleaning particles remaining on a substrate is performed.

In general, the cleaning process removes particles remaining on the substrate by supplying chemicals to the substrate. Recently, however, a cleaning method is used to collect particles with a liquid film of a treatment solution formed by solidification or curing of the treatment solution on a substrate, and to strip the liquid film on the substrate with the particles.

Specifically, after the treatment solution containing the polymer and the volatile solvent is supplied to the substrate, the treatment solution solidified or cured by volatilization of the solvent forms a liquid film. Thereafter, the liquid film is stripped off from the surface of the substrate by supplying a stripping solution, such as pure water, to the substrate, and a dissolution solution, such as isopropyl alcohol, is supplied to the substrate to dissolve the stripped liquid film and remove the liquid film from the substrate.

In the above process, a vortex is formed on the side of the substrate by the rotation of the substrate in the operation of supplying the treatment solution to the upper surface of the rotating substrate or the operation of rotating the substrate at high speed to volatilize the solvent of the treatment solution, which causes the treatment solution remaining on the upper surface of the substrate or mist of the treatment solution to flow into the lower surface of the substrate and contaminate the lower surface of the substrate.

### SUMMARY OF THE INVENTION

The present invention has been made in an effort to provide a substrate processing apparatus and a substrate processing method capable of improving the processing efficiency of a substrate.

The present invention has also been made in an effort to provide a substrate processing apparatus and a substrate processing method capable of preventing contamination of a lower surface of a substrate.

The objectives of the present disclosure are not limited thereto and other objectives not stated herein may be clearly understood by those skilled in the art from the following description.

An exemplary embodiment of the present disclosure, a method of processing a substrate, the method comprising: a fluid supply operation of supplying fluid to a lower surface of a rotating substrate; a treatment solution supply operation of supplying a treatment solution containing a polymer and a volatile solvent to an upper surface of the rotating substrate; after the treatment solution supply operation, a liquid film forming operation of forming a liquid film of the treatment solution by volatilizing the volatile solvent in the treatment solution and solidifying or curing the treatment solution; and after the liquid film forming operation, a liquid film removing operation of removing the liquid film of the treatment solution by supplying a removal solution to the substrate, wherein in the fluid supply operation, the supply of the fluid starts before the liquid film forming operation.

According to the exemplary embodiment of the present invention, wherein in the fluid supply operation, the supply of the fluid may starts before the treatment solution supply operation.

According to the exemplary embodiment of the present invention, wherein in the fluid supply operation, the supply of the fluid may continue during the treatment solution supply operation.

According to the exemplary embodiment of the present invention, wherein in the fluid supply operation, the supply of the fluid may continue during the liquid film forming operation.

According to the exemplary embodiment of the present invention, wherein in the fluid supply operation, the supply of the fluid starts to be provided to the lower surface of the substrate before the treatment solution supply operation and may continue until the liquid film forming operation is completed.

According to the exemplary embodiment of the present invention, wherein the fluid may be a wetting solution that wets the lower surface of the substrate.

According to the exemplary embodiment of the present invention, wherein the fluid supply operation includes: a wetting solution supply operation of supplying a wetting solution that wets the lower surface of the substrate to the lower surface of the rotating substrate; and a gas supply operation of supplying gas forming an airflow to the lower surface of the substrate, and the wetting solution supply operation and the gas supply operation may be performed simultaneously.

According to the exemplary embodiment of the present invention, wherein a liquid deposition point at which the wetting solution is deposited on the lower surface of the substrate is farther from a center of the substrate than a gas deposition point at which the gas may be deposited on the lower surface of the substrate.

According to the exemplary embodiment of the present invention, wherein the wetting solution may be supplied toward the lower surface of the substrate to be inclined upward in a direction away from a central axis of the substrate.

According to the exemplary embodiment of the present invention, wherein the wetting solution may be deionized water.

According to the exemplary embodiment of the present invention, wherein the gas may be inert gas.

According to the exemplary embodiment of the present invention, wherein a temperature of the fluid may be room temperature.

According to the exemplary embodiment of the present invention, wherein a temperature of the fluid may be a temperature higher than room temperature.

An exemplary embodiment of the present disclosure, an apparatus for processing a substrate, the apparatus comprising: a housing having a treatment space; a support unit for supporting and rotating the substrate in the treatment space; a treatment solution supply nozzle for supplying a treatment solution containing a polymer and a volatile solvent to an upper surface of the substrate; a removal solution supply nozzle for supplying a removal solution to the upper surface of the substrate; a fluid supply unit for supplying fluid to a lower surface of the substrate; and a controller for controlling the support unit, the treatment solution supply nozzle, the removal solution supply nozzle, and the fluid supply unit, wherein the controller controls the treatment solution supply nozzle, the removal solution supply nozzle, and the fluid supply unit to sequentially perform: a treatment solution supply operation of supplying a treatment solution containing a polymer and a volatile solvent to an upper surface of the rotating substrate; after the treatment solution supply operation, a liquid film forming operation of forming a liquid film of the treatment solution by volatilizing the volatile solvent in the treatment solution and solidifying or curing the treatment solution; and after the liquid film forming operation, a liquid film removing operation of removing the liquid film of the treatment solution by supplying a removal solution to the substrate, and may perform a fluid supply operation of starting the supply of the fluid to a lower surface of the rotating substrate before the liquid film forming operation.

According to the exemplary embodiment of the present invention, wherein the fluid is a wetting solution, and the fluid supply unit may include a wetting solution supply nozzle that supplies the wetting solution to the lower surface of the substrate.

According to the exemplary embodiment of the present invention, wherein the wetting solution supply nozzle may be provided to discharge the wetting solution inclined upward toward the lower surface of the substrate in a direction away from a central axis of the substrate.

According to the exemplary embodiment of the present invention, wherein the fluid supply unit further includes a gas supply nozzle for supplying gas to the lower surface of the substrate, and the gas supply nozzle may be provided so that a gas deposition point at which the gas is deposited on the lower surface of the substrate is a center of the substrate, or the gas deposition point is closer to the center of the substrate than a liquid deposition point at which the wetting solution is deposited on the lower surface of the substrate.

An exemplary embodiment of the present disclosure, a method of processing a substrate, the method comprising: a wetting solution supply operation of supplying a wetting solution to a lower surface of a rotating substrate; a treatment solution supply operation of supplying a treatment solution containing a polymer and a volatile solvent to an upper surface of the rotating substrate; after the treatment solution supply operation, a liquid film forming operation of forming a liquid film of the treatment solution by volatilizing the volatile solvent in the treatment solution and solidifying or curing the treatment solution; and after the liquid film forming operation, a liquid film removing operation of removing the liquid film of the treatment solution by supplying a removal solution to the substrate, in the wetting solution supply operation, the wetting solution starts to be supplied before the treatment solution supply operation and continues to be supplied until the liquid film forming operation is completed, and the wetting solution may be discharged to be inclined upward toward the lower surface of the substrate in a direction away from a central axis of the substrate.

According to the exemplary embodiment of the present invention, the method may further include a gas supply operation of supplying gas to the lower surface of the substrate, wherein in the gas supply operation, the gas starts to be supplied when the supply of the wetting solution starts, and continues to be supplied until the supply of the wetting solution is completed, and a liquid deposition point at which the wetting solution is deposited on the lower surface of the substrate may be farther from the center of the substrate than a gas deposition point at which the gas is deposited on the lower surface of the substrate.

According to the exemplary embodiment of the present invention, wherein the wetting solution is deionized water, and the gas may be nitrogen gas.

According to the exemplary embodiment of the present invention, it is possible to improve the cleaning efficiency of the substrate.

According to the exemplary embodiment of the present invention, it is possible to prevent the lower surface of the substrate form being contaminated in the process of capturing and removing particles on the substrate by solidification or curing of the treatment solution.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a top plan view schematically illustrating a substrate processing apparatus according to an exemplary embodiment of the present invention.

FIG. 2 is a diagram schematically illustrating a process chamber of FIG. 1 according to the exemplary embodiment.

FIG. 3 is a diagram schematically illustrating an example of a fluid supply unit, a spin chuck, and a rotation shaft of FIG. 2.

FIG. 4 is a diagram illustrating a flow path of a fluid supplied from the fluid supply unit of FIG. 2.

FIG. 5 is a flowchart of a substrate processing method according to an exemplary embodiment of the present invention.

FIG. 6 is a graph schematically illustrating a liquid supply sequence over time in the substrate processing method according to the exemplary embodiment of the present invention.

FIG. 7 is a diagram schematically illustrating an operation state of the substrate processing apparatus before a treatment solution supply operation of FIG. 5.

FIG. 8 is a diagram schematically illustrating an operation state of the substrate processing apparatus in the treatment solution supply operation of FIG. 5.

FIG. 9 is a diagram illustrating a state of the substrate in the treatment solution supply operation of FIG. 5.

FIG. 10 is a diagram schematically illustrating an operation state of the substrate processing apparatus in a liquid film forming operation of FIG. 5.

FIG. 11 is a diagram illustrating a state of the substrate in the liquid film forming operation of FIG. 5.

FIG. 12 is a diagram schematically illustrating an operation state of the substrate processing apparatus in a stripping operation of FIG. 5.

FIG. 13 is a diagram illustrating a state of the substrate in the stripping operation of FIG. 5.

FIG. 14 is a diagram schematically illustrating an operation state of the substrate processing apparatus in a dissolution operation of FIG. 5.

FIG. 15 is a diagram illustrating a state of the substrate in the dissolution operation of FIG. 5.

FIG. 16 is a diagram schematically illustrating an operation state of the substrate processing apparatus in a drying operation of FIG. 5.

FIG. 17 is a diagram illustrating a state of the substrate in the drying operation of FIG. 5.

FIGS. 18 to 20 are diagrams schematically illustrating the fluid supply unit of FIG. 3 according to other exemplary embodiments.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

In addition, the components that transfer the substrate W described below, such as a transfer unit or transfer robots, may be referred to as a transfer module.

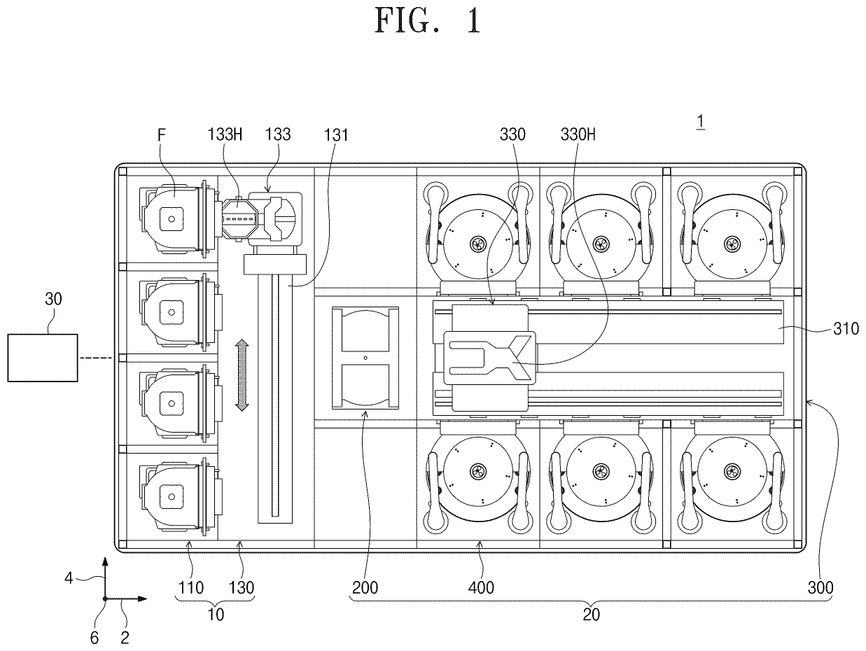

Hereinafter, exemplary embodiment of the present invention will be described with reference to FIGS. 1 to 20.

FIG. 1 is a top plan view schematically illustrating a substrate processing apparatus according to an exemplary embodiment of the present invention. Referring to FIG. 1, a substrate processing apparatus 1 includes an index module 10, a treating module 20, and a controller 30. According to the exemplary embodiment, the index module 10 and the treating module 20 are disposed along one direction. Hereinafter, the direction in which the index module 10 and the treating module 20 are disposed is referred to as a first direction 2, and when viewed from above, a direction perpendicular to the first direction 2 is referred to as a second direction 4, and a direction perpendicular to a plane including both the first direction 2 and the second direction 4 is referred to as a third direction 6.

The index module 10 transfers a substrate W from a container F in which the substrate W is accommodated to the treating module 20 treating the substrate W. The index module 10 accommodates the substrate W completely treated in the treating module 20 into the container F. A longitudinal direction of the index module 10 is provided in the second direction 4. The index module 10 includes a load port 110 and an index frame 130.

The container F in which the substrate W is accommodated is seated on the load port 110. Based on the index frame 130, the load port 110 is located at a side opposite to the treating module 20. A plurality of load ports 110 may be provided. The plurality of load ports 110 may be arranged in a line along the second direction 4. The number of load ports 110 may increase or decrease according to the process efficiency and footprint conditions of the treating module 20.

A plurality of slots (not illustrated) for accommodating the substrates W in a state of being horizontally arranged with respect to the ground is formed in the carrier F. As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index rail 131 and an index robot 133 are provided in the index frame 130. The index rail 131 is provided in the index frame 130 along the second direction 4 in its longitudinal direction. The index robot 133 may transfer the substrate W. The index robot 133 may transfer the substrate W between the index module 10 and a buffer unit 200 to be described later.

The index robot 133 may be provided on the index rail 131 to be movable along the second direction 4. The index robot 133 includes a hand 133H. The substrate W may be placed on the hand 133H. The hand 133H is provided to be able to move forward and backward in the first direction 2. Also, the hand 133H may be provided to rotate around the third direction 6 and be movable along the third direction 6. A plurality of hands 133H may be provided. A plurality of hands 133H may be provided to be spaced apart from each other in the vertical direction. A plurality of hands 133H may move forward, backward, and rotate independently of each other.

The treating module 20 includes a buffer unit 200, a transfer chamber 300, and a process chamber 400. The buffer unit 200 provides a space in which the substrate W loaded into the treating module 20 and the substrate W unloaded from the treating module 20 stay temporarily. The transfer chamber 300 provides a space for transferring the substrate W between the buffer unit 200 and the process chamber 400 and between the process chambers 400. The process chamber 400 may perform a liquid treatment process for liquid-treating the substrate W by supplying liquid onto the substrate W. For example, the liquid treatment process may be a cleaning process for cleaning the substrate W with a cleaning solution.

The buffer unit 200 may be disposed between the index frame 130 and the transfer chamber 300. The buffer unit 200 may be located at one end of the transfer chamber 300. A slot (not illustrated) in which the substrate W is placed is provided in the buffer unit 200. A plurality of slots (not illustrated) is provided to be spaced apart from each other along the third direction 6. A front face and a rear face of the buffer unit 200 are opened. The front face is a face facing the index module 10, and the rear face is a face facing the transfer frame 300. The index robot 133 may approach the buffer unit 200 through the front face, and the transfer robot 330 to be described below may approach the buffer unit 200 through the rear face.

The transfer chamber 300 may be provided so that a longitudinal direction is the first direction 2. The process chambers 400 may be disposed on opposite sides of the transfer chamber 300, respectively. The process chamber 400 may be disposed on a side portion of the transfer chamber 300. The transfer chamber 300 and the process chamber 400 may be disposed along the second direction 4.

According to an example, the process chambers 400 may be disposed at opposite sides of the transfer chamber 300, and the process chambers 400 may be provided in an arrangement of A×B (where A and B are each natural number equal to or greater than 1) at one side of the transfer chamber 300 along the first direction 2 and the third direction 6, respectively. Herein, A is the number of process chambers 400 provided in a row along the first direction 2, and B is the number of process chambers 400 provided in a row along the third direction 6. For example, when four or six process chambers 400 are provided at one side of the transfer chamber 300, the process chambers 400 may be arranged in a 2×2 or 2×3 arrangement. The number of process chambers 400 may increase or decrease. Unlike the above description, the process chamber 400 may be provided only at one side of the transfer chamber 300. Also, the process chamber 400 may be provided as a single layer at one side or opposite sides of the transfer chamber 300.

The transfer chamber 300 includes a guide rail 310 and a transfer robot 330. The guide rail 310 is provided within the transfer chamber 300 in the first direction 2 in a longitudinal direction thereof. The transfer robot 330 may be provided on the guide rail 310 to be able to move linearly along the first direction 2. The transfer robot 330 transfers the substrate W between the buffer unit 200 and the process chamber 400 and between the process chambers 400.

The transfer robot 330 includes a hand 330H on which the substrate W is placed. The hand 330H may be provided on the guide rail 310 to be movable along the first direction 2. Accordingly, the hand 330H may be moved forward and backward along the guide rail 310. In addition, the hand 330H may be provided to rotate around the third direction 6 and be movable along the third direction 6. A plurality of hands 330H may be provided. A plurality of hands 330H may be provided to be spaced apart from each other in the vertical direction. The plurality of hands 330H may move forward, backward, and rotate independently of each other.

The process chamber 400 performs a process of liquid-treating the substrate W. For example, the process chamber 400 may be a chamber for performing a cleaning process for removing process by-products or the like attached to the substrate W. Each of the process chambers 400 may have the same structure. Alternatively, the process chamber 400 may have different structures depending on the type of process for treating the substrate W.

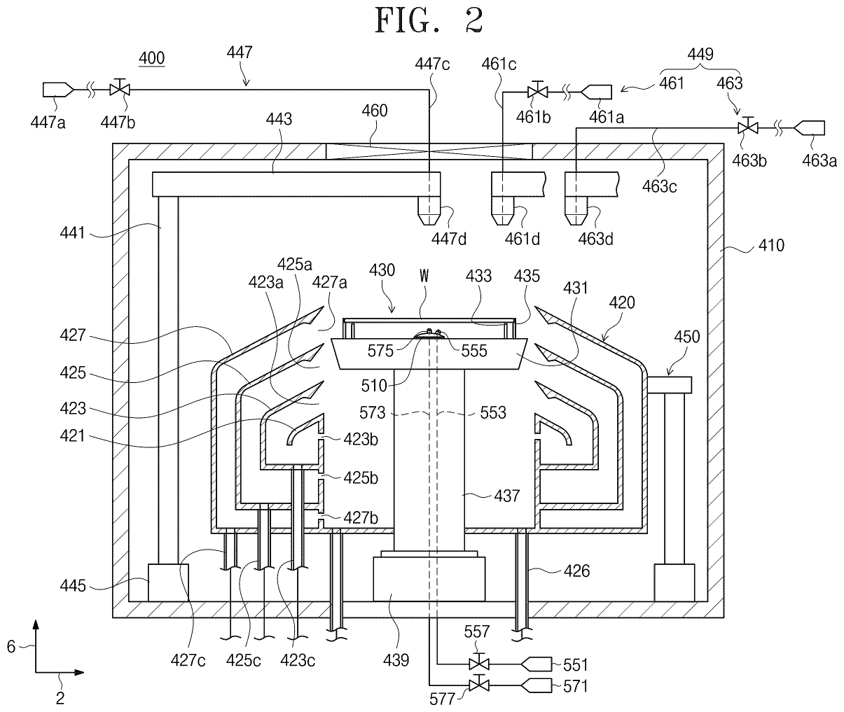

FIG. 2 is a diagram schematically illustrating the process chamber of FIG. 1 according to the exemplary embodiment. The process chamber 400 includes a housing 410, a treatment container 420, a support unit 430, a liquid supply unit 440, a lifting unit 450, and a fluid supply unit 500.

The housing 410 has an inner space. The housing 410 is provided in a generally rectangular parallelepiped shape. An opening (not illustrated) is formed at one side of the housing 410. The opening (not illustrated) functions as an entrance through which the substrate W is loaded into the inner space or the substrate W is unloaded from the inner space. The treatment container 420, the support unit 430, the liquid supply unit 440, and the fluid supply unit 500 are disposed in the housing 410.

The treatment container 420 provides a treatment space in which the substrate W is processed. The treatment container 420 has a treatment space with an open top. The treatment container 420 may have a bowl shape.

The treatment container 420 may include a guide wall 421, a first recovery container 423, a second recovery container 425, and a third recovery container 427. Each of the recovery containers 423, 425, and 427 separates and recovers a different liquid from among liquids used for the treatment of the substrate W. Each of the plurality of recovery containers 423, 425, and 427 has a recovery space for recovering a treatment solution C1 used for processing the substrate W.

The first recovery container 423 is provided in an annular ring shape surrounding the guide wall 421, and the second recovery container 425 is provided in an annular ring shape surrounding the first recovery container 423. The third recovery container 427 is provided in a ring shape surrounding the second recovery container 425. A space between the first recovery container 423 and the guide wall 421 functions as a first inlet 423a through which a liquid is introduced. A space between the first recovery container 423 and the second recovery container 425 functions as a second inlet 425a through which a liquid is introduced. A space between the second recovery container 425 and the third recovery container 427 functions as a third inlet 427a through which a liquid is introduced. The second inlet 425a is located above the first inlet 423a, and the third inlet 427a is located above the second inlet 425a.

The space between the lower end of the guide wall 421 and the first recovery container 423, the space between the lower end of the first recovery container 423 and the second recovery container 425, and the space between the lower end of the second recovery container 425 and the third recovery container 427 function as outlets 423b, 425b, and 427b through which fumes and gas generated from the liquid are discharged, respectively.

An exhaust pipe 429 is coupled to the lower end of the treatment container 420. For example, the exhaust pipe 429 may be coupled to the lower end of the treatment container 420 between the plurality of recovery containers 423, 425, and 427 and the support unit 430. The exhaust pipe 429 exhausts fumes and gas discharged from the respective outlets 423b, 425b, and 427b to the outside of the treatment space. A pressure reducing pump (not illustrated) may be installed at the exhaust pipe 429.

Recovery lines 423c, 425c, and 427c extending vertically in a direction below the bottom surfaces of the recovery containers 423, 425, and 427 are connected to the recovery containers 423, 425, and 427, respectively. The recovery lines 423c, 425c, and 427c discharge the treatment solution C1 introduced through the recovery containers 423, 425, and 427, respectively. The discharged treatment solution C1 may be reused by an external liquid regeneration system (not illustrated).

The support unit 430 supports and rotates the substrate W in the treatment space. The support unit 430 includes a spin chuck 431, a support pin 433, a chuck pin 435, a rotation shaft 437, and a driver 439.

The top surface of the spin chuck 431 is generally provided in a circular shape when viewed from the top. The top surface of the spin chuck 431 may be provided to have a larger diameter than the substrate W. When viewed from above, the spin chuck 431 has a through hole formed in a central region. A fixed shaft 530 to be described later may be inserted into the through hole of the spin chuck 431.

A plurality of support pins 433 is provided. The support pin 433 is disposed on the top surface of the spin chuck 431. The support pin 433 is disposed on the edge of the top surface of the spin chuck 431 to be spaced apart from each other at a predetermined interval. The support pin 433 protrudes from the top surface of the spin chuck 431. The support pins 433 are disposed to have an annular ring shape as a whole by a combination thereof. The support pin 433 supports the rear edge area of the substrate W so that the substrate W is spaced apart from the top surface of the spin chuck 431 by a predetermined distance.

A plurality of chuck pins 435 is provided. The chuck pin 435 is disposed to be relatively farther from the center of the spin chuck 433 than the support pin 431. The support pin 435 protrudes from the top surface of the spin chuck 431. The chuck pin 335 supports a side portion of the substrate W so as not to be separated from the correct position in the lateral direction when the substrate W is rotated. The chuck pin 435 is provided to be able to move linearly between a standby position and a support position along a radial direction of the spin chuck 431. For example, the chuck pin 435 may be linearly moved in the radial direction of the substrate W between the standby position and the support position. The standby position is a position farther from the center of the spin chuck 431 than the support position. When the substrate W is loaded or unloaded on the support unit 430, the chuck pin 435 is located at the standby position, and the chuck pin 435 is located at the support position when performing a process on the substrate W. In the support position, the chuck pin 435 is in contact with the side portion of the substrate W.

The rotation shaft 437 is coupled to the spin chuck 431. For example, the rotation shaft 437 may be coupled to a lower surface of the spin chuck 431. The rotation shaft 437 may be provided such that a longitudinal direction thereof faces a vertical direction. The rotation shaft 437 is provided as a hollow shaft having an empty inside. A fixed shaft 530 to be described later may be inserted into the rotation shaft 437. The rotation shaft 437 is provided to be rotatable by receiving power from the driver 439. The rotation shaft 437 is rotated by the driver 439, thereby rotating the spin chuck 431. The driver 439 may vary the rotation speed of the rotation shaft 437. The driver 439 may be a motor that provides driving force.

The liquid supply unit 440 supplies a liquid onto the upper surface of the substrate W. The liquid supply unit 440 supplies the liquid to the upper surface of the substrate W supported by the support unit 430. The liquid supply unit 440 may sequentially supply a plurality of liquids onto the substrate W. The liquid supply unit 440 includes a treatment solution supply unit 447 and a removal solution supply unit 449.

The treatment solution supply unit 447 supplies the treatment solution C1 onto the substrate W. The treatment solution supply unit 447 includes a support rod 441, an arm 443, and a driver 445.

The support rod 441 has a rod shape whose longitudinal direction faces the third direction 6. The support rod 441 is provided to be rotatable with respect to its central axis by the driver 445 to be described later.

The arm 443 is coupled to an upper end of the support rod 441. The arm 443 extends vertically from the longitudinal direction of the support rod 441. The treatment solution supply nozzle 447d is fixedly coupled to the end of the arm 443. The arm 443 swings and moves between a process position and the standby position by rotation of the support rod 441.

The process position is a position where the treatment solution supply nozzle 447d faces the substrate W supported by the support unit 430 when viewed from above. The standby position is a position where the treatment solution supply nozzle 447d is out of the process position when viewed from above.

The driver 445 is coupled with the support rod 441. The driver 445 provides driving force for rotating the support rod 441. The driver 445 may be a known motor for providing driving force.

The treatment solution supply nozzle 447d supplies the treatment solution C1. The treatment solution supply nozzle 447d supplies the treatment solution C1 onto the substrate W supported by the support unit 430. The treatment solution C1 includes a polymer and a volatile solvent. The polymer may include a resin. The resin may be an acrylic resin, a phenol resin, an epoxy resin, a polystyrene resin, a polyester resin, an alkyd resin, a polyurethane, polyimide, polyethylene, polypropylene, polyvinyl chloride, polyvinyl acetate, polyamide, or another type of resin. The volatile solvent contains alcohol. The volatile solvent may be a solution for dissolving a polymer. When the volatile solvent is volatilized in the treatment solution C1 supplied onto the substrate W, the treatment solution C1 is solidified or cured on the substrate W to form a liquid film S of the treatment solution C1 on the substrate.

The treatment solution C1 is supplied from a treatment solution supply source 447a to a treatment solution supply nozzle 447d through a treatment solution supply line 447c. The treatment solution supply valve 447b is installed on the treatment solution supply line 447c to open and close the internal flow path.

The removal solution supply unit 449 supplies the removal solution onto the substrate W. According to an example, the removal solution may include a stripping solution C4 and a dissolution solution C5. Optionally, the removal solution supply unit 449 may include a stripping solution supply unit 461 and a dissolution solution supply unit 463.

The stripping solution C4 is supplied from a stripping solution supply source 461a to a stripping solution supply nozzle 461d through a stripping solution supply line 461c. The stripping solution supply valve 461b is installed on the stripping solution supply line 461c to open and close an internal flow path.

The stripping solution C4 is a liquid that penetrates between the liquid films S formed on the substrate W to separate the liquid film S from the substrate W. For example, the stripping solution C4 may be Deionized Water (DIW).

The dissolution solution C5 is supplied from a dissolution solution supply source 463a to a dissolution solution supply nozzle 463d through a dissolution solution supply line 463c. The dissolution solution supply valve 463b is installed on the dissolution solution supply line 463c to open and close the internal flow path.

The dissolution solution C5 may be a dissolution solution for dissolving the liquid film S. The dissolution solution C5 may include an alcohol for dissolving a resin. For example, the dissolution solution C5 may be isopropyl alcohol having a concentration of 100%.

Since the stripping solution supply unit 461 and the dissolution solution supply unit 463 have the same or similar structure as the treatment solution supply unit 447, detailed description thereof will be omitted below.

The lifting unit 450 is disposed in the housing 410. The lifting unit 450 adjusts the relative height between the treatment container 420 and the support unit 430. The lifting unit 450 may linearly move the treatment container 320 in the third direction 6. Unlike the description, the treatment container 420 is fixedly installed, and the lifting unit 450 may move the support unit 440 in the vertical direction.

The airflow supply unit 460 supplies airflow to the inner space of the housing 410. The airflow supply unit 460 is installed on the ceiling of the housing 410. Gas supplied to the inner space of the housing 410 through the airflow supply unit 460 forms a descending airflow in the inner space. Gas by-products generated by the treatment process in the treatment space are discharged to the outside of the housing 410 through the exhaust pipe 429 by the descending airflow. The airflow supply unit 460 may be provided to a Fan Filter Unit (FFU).

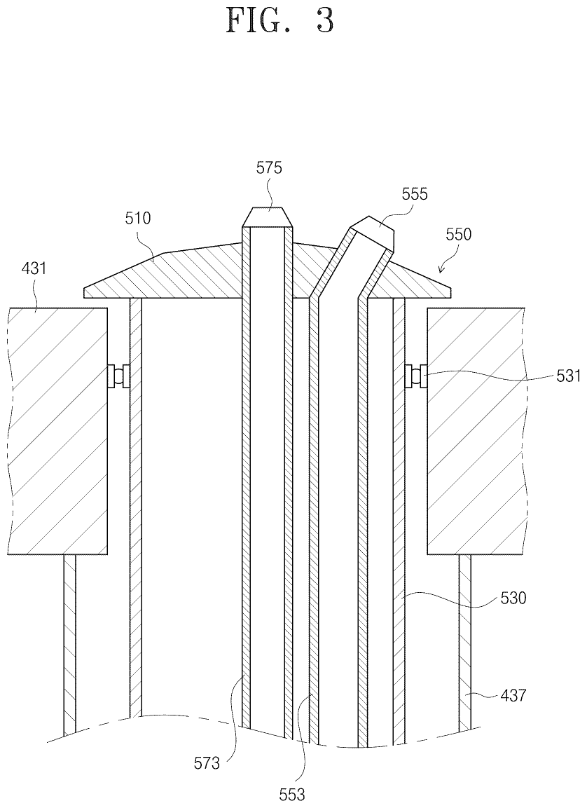

The fluid supply unit 500 supplies the fluid to the lower surface of the substrate W. For example, the fluid supply unit 500 may supply a wetting solution C3 and gas G to the lower surface of the substrate W. FIG. 3 is a diagram schematically illustrating an example of the fluid supply unit, the spin chuck, and the rotation shaft of FIG. 2. The fluid supply unit 500 may include an injection body 510, a fixed shaft 530, a wetting solution supply unit 550, and a gas supply unit 570.

The injection body 510 is coupled to the upper end of the fixed shaft 530. A plurality of holes may be formed in the injection body 510. A wetting solution supply pipe 553 and a gas supply pipe 573 to be described later are inserted into a plurality of holes formed in the injection body 510.

The fixed shaft 530 is inserted into the through hole formed in the spin chuck 431 and the rotation shaft 437. The fixed shaft 530 is spaced apart from the rotation shaft 437. A bearing 531 is installed between the outer surface of the fixed shaft 530 and the spin chuck 431. Accordingly, even if the spin chuck 431 rotates, the fixed shaft 530 may be fixed without rotating.

The wetting solution supply unit 550 supplies the wetting solution C3 to the lower surface of the substrate W. The wetting solution supply unit includes a wetting solution supply source 551, a wetting solution supply pipe 553, and a wetting solution supply nozzle 555.

The wetting solution supply source 551 stores the wetting solution C3. The wetting solution C3 may be a liquid that wets the lower surface of the substrate W. According to an example, the wetting solution C3 may be Deionized Water (DIW).

The wetting solution supply pipe 553 feeds the wetting solution C3 from the wetting solution supply source 551 to the wetting solution supply nozzle 555. The wetting solution supply pipe 553 may be located in the inner space of the fixed shaft 530. The wetting solution supply pipe 553 is provided with a wetting solution supply valve 557 for opening and closing the inside thereof.

The wetting solution supply nozzle 555 discharges the wetting solution C3 supplied from the wetting solution supply source 551 to the lower surface of the substrate W. The wetting solution supply nozzle 555 is provided to be inclined upward in a direction away from the central axis of the substrate W. According to an example, the wetting solution supply nozzle 555 may be provided to be inclined upward at an angle between 40 degrees and 60 degrees with respect to the central axis of the substrate W in a direction away from the central axis.

The gas supply unit 570 supplies the gas G to the lower surface of the substrate W. The gas supply unit 570 includes a gas supply source 571, a gas supply pipe 553, and a gas supply nozzle 555.

The gas supply source 571 stores gas G. The gas G may be inert gas. According to an example, the gas G may be nitrogen gas.

The gas supply pipe 573 delivers the gas G from the gas supply source 571 to the gas supply nozzle 575. The gas supply pipe 573 may be located in the inner space of the fixed shaft 530. The gas supply pipe 573 is provided with a gas supply valve 577 that opens and closes the inside thereof.

The gas supply nozzle 575 discharges the gas G supplied from the gas supply source 571 to the lower surface of the substrate W. The gas supply nozzle 575 may supply the gas G to the lower surface of the substrate W in a direction parallel to the central axis of the substrate W. For example, the gas supply nozzle 575 may supply the gas G to the central region of the lower surface of the substrate W.

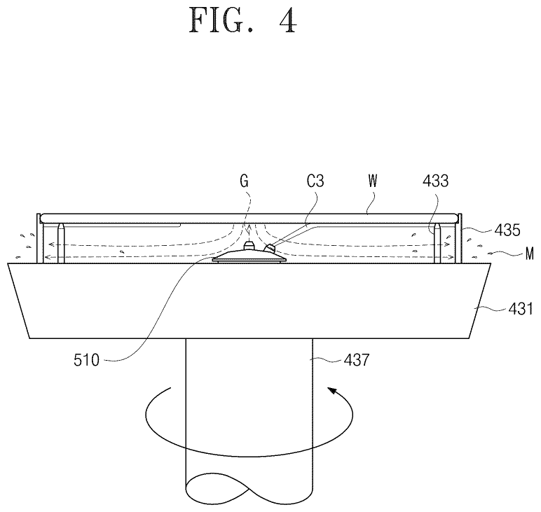

FIG. 4 is a diagram illustrating a flow path of a fluid supplied from the fluid supply unit of FIG. 2.

Referring to FIG. 4, the wetting solution supply nozzle 555 may wet the edge region of the lower surface of the substrate W to prevent the treatment solution supplied to the upper surface of the substrate W or mist M of the treatment solution from adhering to the edge region of the lower surface of the substrate W. The gas G supplied by the gas supply nozzle 575 may form an outward airflow in the space between the lower surface of the substrate W and the spin chuck 431, thereby preventing the treatment solution or the mist M of the treatment solution from entering the edge region of the substrate W.

The temperature of the wetting solution C3 and the gas G supplied to the lower surface of the substrate W is a temperature within a range in which the treatment solution C1 does not affect the process environment in which the liquid film S is formed. According to an example, the temperature of the wetting solution C3 and the gas G may be room temperature or a temperature higher than room temperature. For example, the temperatures of the wetting solution C3 and the gas G may be 23° C. to 30° C.

Hereinafter, a substrate processing method according to an exemplary embodiment of the present invention will be described in detail. The substrate processing method described below may be performed by the process chamber 400. Also, the controller 30 may control the components of the process chamber 400 so that the process chamber 400 may perform the substrate processing method described below.

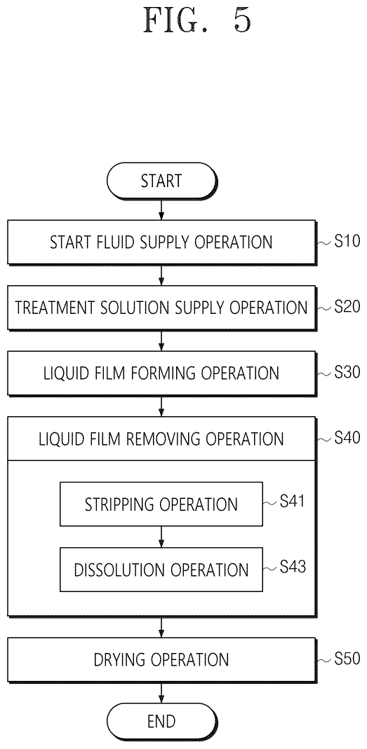

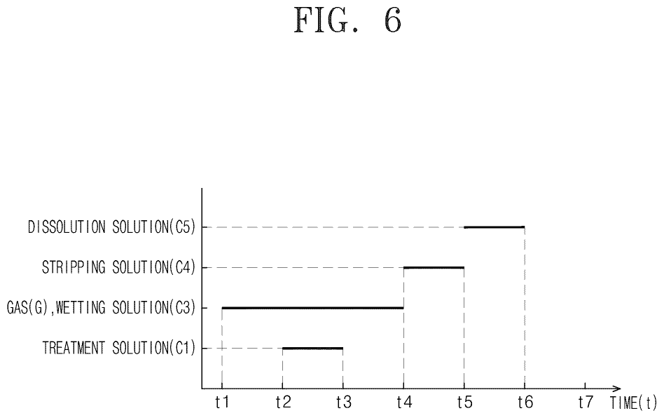

FIG. 5 is a flowchart of a substrate processing method according to an exemplary embodiment of the present invention, and FIG. 6 is a graph schematically illustrating a liquid supply sequence over time. Referring to FIG. 5, the substrate processing method includes a fluid supply operation S10, a treatment solution supply operation S20, a liquid film forming operation S30, a liquid film removing operation S40, and a drying operation S50. The liquid film removing operation S40 includes a stripping operation S41 and a dissolution operation S43.

Referring to FIGS. 5 to 6, in the treatment solution supply operation S20, the treatment solution C1 is supplied to the substrate W for a time ranging from t2 to t3. Thereafter, the liquid film forming operation S30 is performed for a time ranging from t3 to t4, and after the liquid film forming operation S30, the stripping operation S41 is performed to supply the stripping solution C4 to the substrate W for a time ranging from t4 to t5. After the stripping operation S41, the dissolution operation S43 is performed to supply the dissolution solution C5 to the substrate W for a time ranging from t5 to t6, and then the drying operation S50 is performed for a time ranging from t6 to t7. The fluid supply operation S10 starts at t1, which is before the treatment solution supply operation S10, and supplies the wetting solution C3 and the gas G until the end of the liquid film forming operation S30.

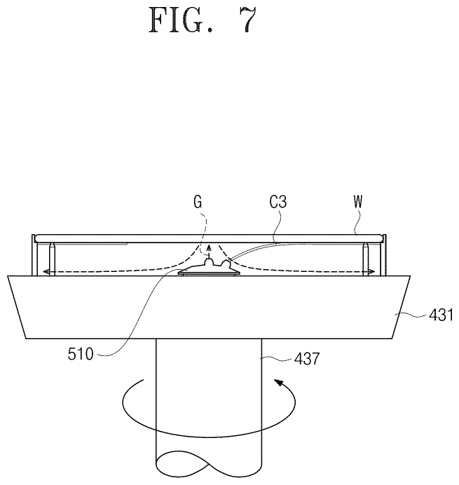

FIGS. 7 to 17 are diagrams illustrating an operation state of the substrate processing apparatus in each operation or a state of a specific part of the substrate.

FIGS. 7, 8, 10, 12, 14, and 16 are diagrams schematically illustrating operation states of the substrate processing apparatus in the fluid supply operation before the treatment solution supply operation, the treatment solution supply operation, the liquid film forming operation, the stripping operation, the dissolution operation, and the drying operation, respectively. FIGS. 9, 11, 13, 15, and 17 are diagrams schematically illustrating the states of the substrate in the treatment solution supply operation, the liquid film forming operation, the stripping operation, the dissolution operation, and the drying operation, respectively.

When the substrate W is placed on the spin chuck 431, the fluid supply operation S10 is performed. In the fluid supply operation S10, the wetting solution C3 and the gas G are supplied to the lower surface of the rotating substrate W.

Referring to FIG. 7, the treatment solution supply nozzle 447d, the stripping liquid supply nozzle 461d, and the dissolution solution supply nozzle 463d are placed in the standby position. The treatment solution supply valve 447b, the stripping liquid supply valve 461b, and the dissolution solution supply valve 463b are closed, and the wetting solution supply valve 557 and the gas supply valve 577 are opened.

When the substrate W is rotated, the wetting solution supply nozzle 555 and the gas supply nozzle 575 supply the wetting solution C3 and the gas G to the lower surface of the substrate W, respectively. The wetting solution C3 is supplied to the edge region of the lower surface of the substrate W to wet the edge region of the lower surface of the substrate W. The gas G is supplied to the central region of the lower surface of the substrate W to form an airflow in a direction from the center to the edge of the substrate W. The wetting solution C3 and the gas G may be supplied at the same time.

After a predetermined time has elapsed after the fluid supply operation S10 starts, the treatment solution supply operation S20 is performed. In the treatment solution supply operation S20, the treatment solution C1 is supplied onto the rotating substrate W.

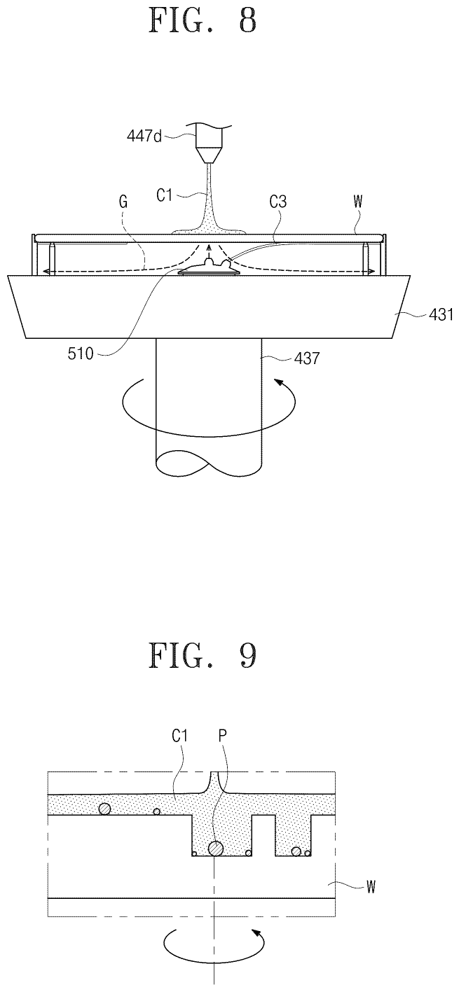

Referring to FIG. 8, the treatment solution supply nozzle 447d is placed at the process position, and the stripping liquid supply nozzle 461d and the dissolution solution supply nozzle 463d are placed at the standby position. In the treatment solution supply operation S20, the treatment solution supply valve 447b, the wetting solution supply valve 557, and the gas supply valve 577 are opened, and the stripping liquid supply valve 461b and the dissolution solution supply valve 463b are closed.

The treatment solution C1 is supplied from the treatment solution supply nozzle 447d toward the center of the upper surface of the substrate W, and the treatment solution C1 supplied to the substrate W spreads from the central region of the substrate W to the edge region by the rotation of the substrate W and is applied to the entire substrate W. The wetting solution C3 and the gas G are supplied to the lower surface of the substrate W, and the treatment solution or the mist M of the treatment solution supplied to the upper surface of the substrate W is prevented from adhering to the lower surface of the substrate W.

Referring to FIG. 9, the treatment solution C1 supplied to the substrate W fills between a plurality of patterns on the substrate W and covers the entire upper surface of the pattern formed on the substrate W.

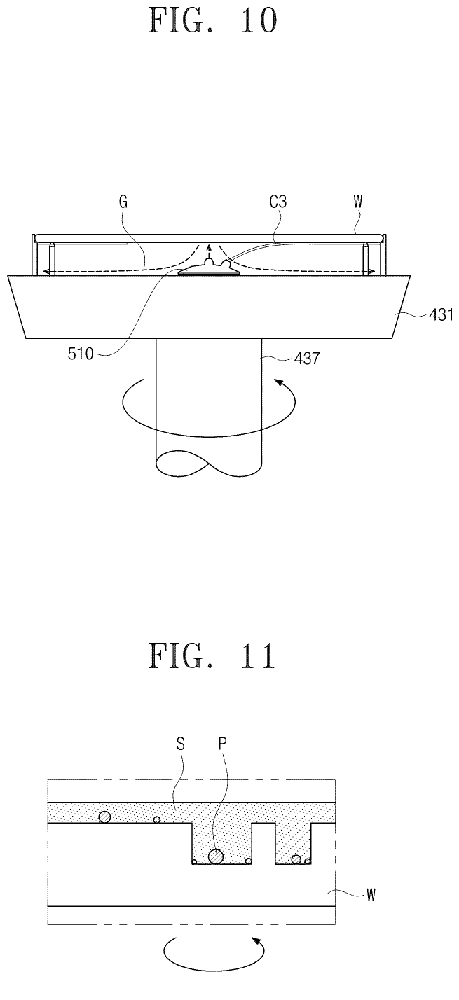

When the treatment solution supply operation S20 is completed, the liquid film forming operation S30 is performed. In the liquid film forming operation S30, the substrate W rotates without supplying liquid. Referring to FIG. 10, a volatile solvent in the treatment solution C1 is volatilized by the rotation of the substrate W, and the treatment solution C1 is solidified or cured. As a result, the liquid film S of the treatment solution C1 is formed on the upper surface of the substrate W.

In the liquid film forming operation S30, the wetting solution supply valve 557 and the gas supply valve 577 are opened, and the treatment solution supply valve 447b, the stripping solution supply valve 461b, and the dissolution solution supply valve 463b are closed. The wetting solution C3 and the gas G are supplied to the lower surface of the substrate W to prevent the treatment solution or the mist M of the treatment solution from adhering to the lower surface of the substrate W.

Referring to FIG. 11, as the volatile solvent volatilizes, volume contraction of the treatment solution C1 occurs. As the volatile solvent continuously volatilizes, the treatment solution C1 is solidified or cured, and in this process, the particles P remaining on the substrate W are dropped from the substrate W due to the tension caused by volume contraction and are trapped in the liquid film S of the treatment solution C1.

When the liquid film forming operation S30 is completed, the fluid supply operation S10 is finished, and the stripping operation S41 starts.

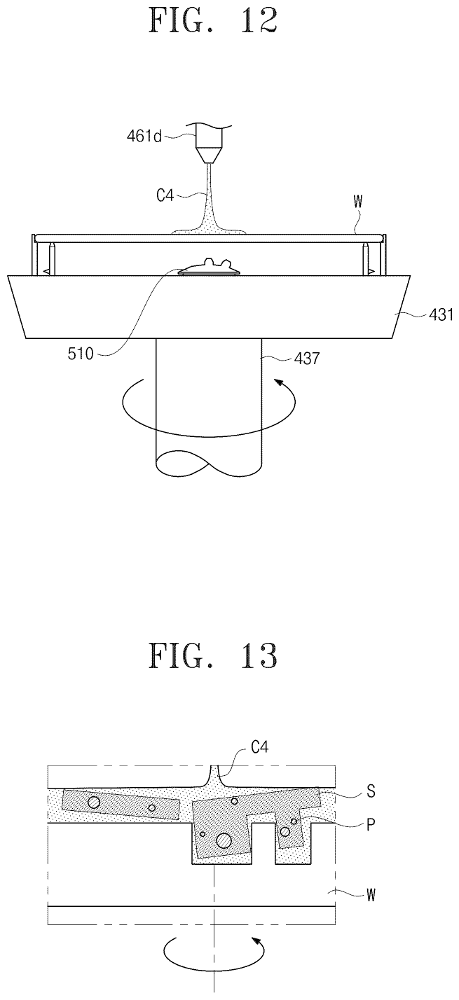

Referring to FIG. 12, the stripping liquid supply nozzle 461d is placed in the process position, and the treatment solution supply nozzle 447d and the dissolution solution supply nozzle 463d are placed in the standby position. The stripping solution supply valve 461b is opened and the stripping solution C4 is supplied onto the rotating substrate W. In this case, the treatment solution supply valve 447b, the dissolution solution supply valve 463b, the wetting solution supply valve 557, and the gas supply valve 577 are closed.

The stripping solution supply nozzle 461d supplies the stripping solution C4 to the central region of the substrate W. By rotation of the substrate W, the stripping solution C4 spreads from the central region of the substrate W to the edge region and is applied to the entire substrate W.

Referring to FIG. 13, the stripping solution C4 penetrates between the liquid films S formed in the liquid film forming operation S30 to strip the liquid film S from the substrate W.

When the stripping operation S41 is completed, the dissolution operation S43 starts.

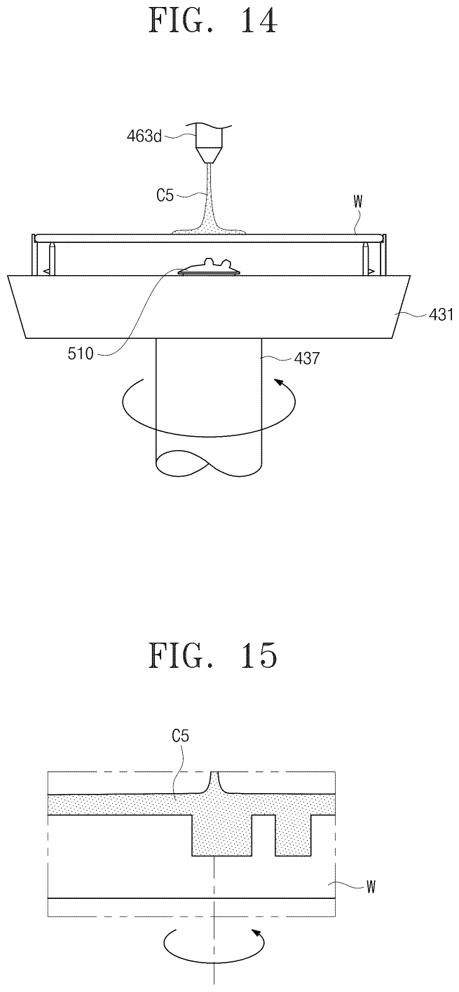

Referring to FIG. 14, the dissolution solution supply nozzle 463d is placed in the process position, and the treatment solution supply nozzle 447d and the stripping solution supply nozzle 461d are placed in the standby position. The dissolution solution supply valve 463b is opened and the dissolution solution C5 is supplied onto the rotating substrate W. In this case, the treatment solution supply valve 447b, the stripping solution supply valve 461b, the wetting solution supply valve 557, and the gas supply valve 577 are closed.

The dissolution solution supply nozzle 463d supplies the dissolution solution C5 to the central region of the substrate W. By rotation of the substrate W, the dissolution solution C5 spreads from the central region of the substrate W to the edge region and is applied to the entire substrate W.

Referring to FIG. 15, the dissolution solution C5 dissolves the liquid film S stripped off in the stripping operation S43 to remove the liquid film S from the substrate W.

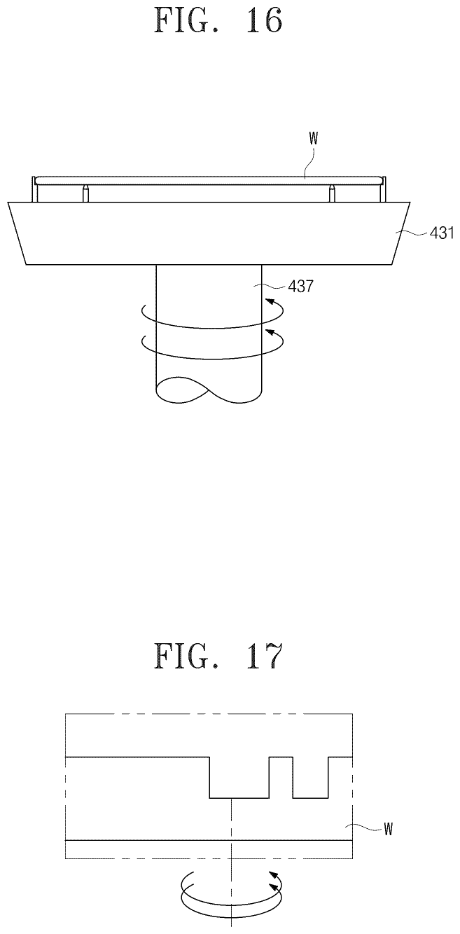

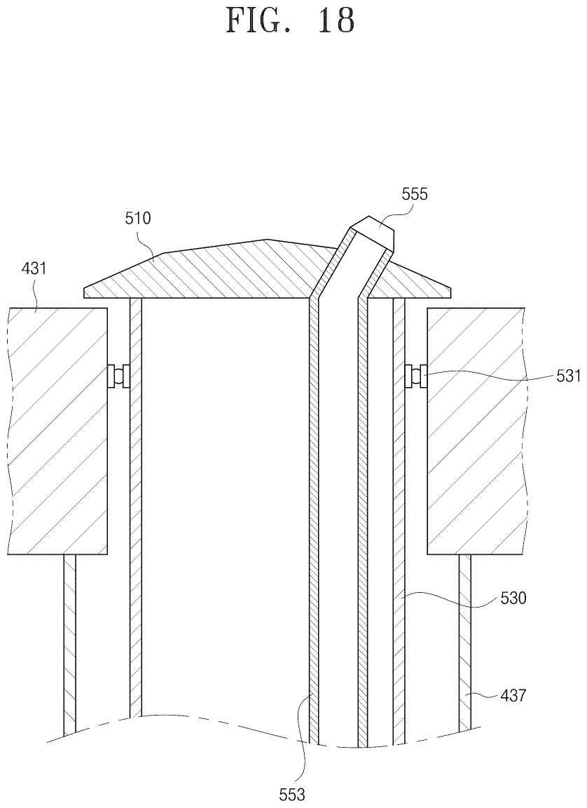

After the dissolving operation S43, the drying operation S50 starts. Referring to FIGS. 16 and 17, in the drying operation S50, the dissolution solution C5 remaining on the substrate W after the liquid film removing operation S40 is dried. In the drying operation S50, the substrate W is rotated at a high speed while the liquid supply to the substrate W is stopped, and the dissolution solution C5 remaining on the substrate W is volatilized by centrifugal force.

In the above-described exemplary embodiment of FIG. 3, the case where one wetting solution supply nozzle 555 is present has been described as an example. However, unlike this, a plurality of wetting solution supply nozzles 555 may be provided, and the plurality of wetting solution supply nozzles 555 may be provided in a structure surrounding the gas supply nozzle 575 at regular intervals.

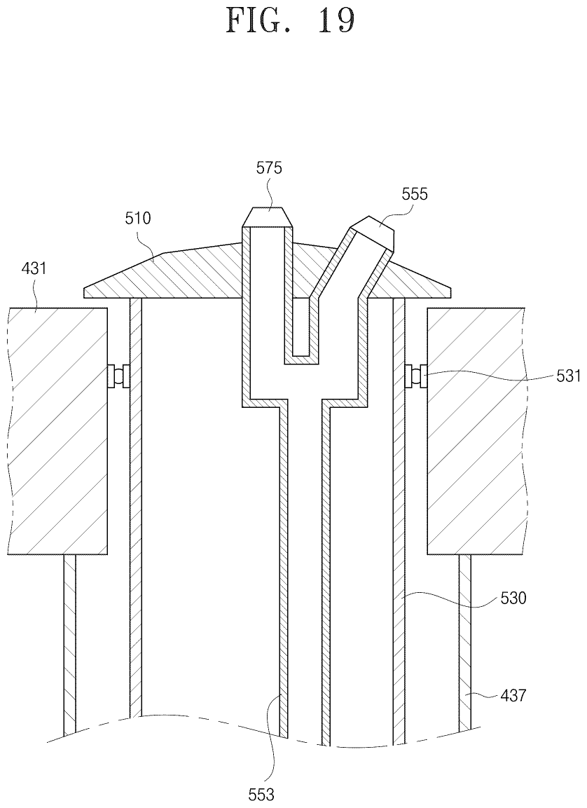

In the above-described exemplary embodiment of FIG. 3, the case where the wetting solution supply nozzle 555 and the gas supply nozzle 575 supply the wetting solution C3 and the gas G to the lower surface of the substrate W, respectively, has been described as an example. However, unlike this, the gas supply nozzle 575 is not provided as in FIG. 18, and the wetting solution supply nozzle 555 may supply the wetting solution C3 to an edge region of the lower surface of the substrate W. However, the present invention is not limited thereto, and only the gas supply nozzle 575 may be provided without the wetting solution supply nozzle 555, and as illustrated in FIG. 19, the gas supply nozzle 575 is not provided, and a plurality of wetting solution supply nozzles 555 may be provided to supply the wetting solution C3 to the central region and the edge region of the substrate W.

In the above-described exemplary embodiment of FIG. 5, the case where the liquid film removing operation S40 is sequentially performed by the stripping operation S41 of supplying the stripping solution C4 onto the substrate W and the dissolution operation S43 of supplying the dissolution solution C5 onto the substrate W has been described as an example. However, unlike this, the stripping operation S41 and the dissolution operation S43 may be performed simultaneously. Accordingly, the stripping solution C4 and the dissolution solution C5 may be simultaneously supplied to the substrate W to perform the liquid treatment on the substrate W. Selectively, the removal solution in which the stripping solution C4 and the dissolution C5 are mixed may be supplied to the substrate W.

Also, in the exemplary embodiment of FIG. 5, it has been described that the liquid film removing operation S40 includes both the stripping operation S41 and the dissolution operation S43. However, unlike this, the liquid film removing operation S40 may include only one of the stripping operation S41 and the dissolution operation S43.

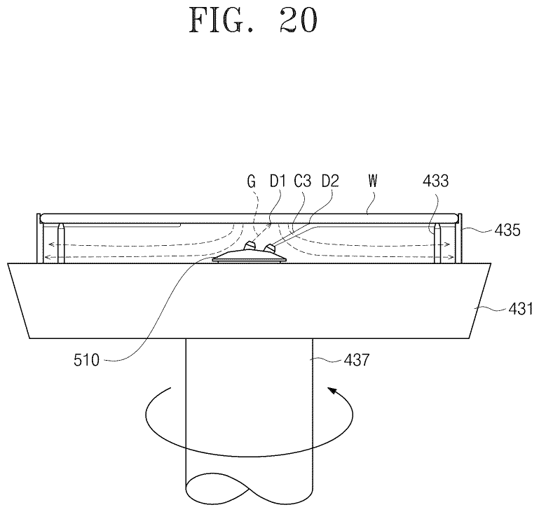

In the exemplary embodiment of FIG. 4 described above, the case where the gas supply nozzle 575 supplies the gas G to the lower surface of the substrate W in a direction parallel to the central axis of the substrate W has been described as an example. However, unlike this, as illustrated in FIG. 20, the gas supply nozzle 575 may be provided to be inclined upward in a direction away from the central axis of the substrate W. In this case, the degree of inclination of the gas supply nozzle 575 may be determined so that a liquid deposition point D1 at which the wetting solution C3 supplied from the wetting solution supply nozzle 555 is deposited on the lower surface of the substrate W is farther from the central axis of the substrate W than a gas deposition point D2 at which the gas G is deposited on the lower surface of the substrate W.

In the above-described exemplary embodiment of FIG. 2, the case where the treatment solution supply unit 447 and the removal solution supply unit 449 have different arms, and these arms are driven independently of each other has been described as an example, but unlike this, the treatment solution supply nozzle 447d, the stripping solution supply nozzle 461d, and the dissolution solution supply nozzle 463d may be coupled to the same arm and driven.

In the exemplary embodiments of FIGS. 5 to 6, it has been described that the fluid supply operation S10 starts before the treatment solution supply operation S20 and is performed until the liquid film forming operation S30 is completed. However, unlike this, the fluid supply operation S10 may be started when the treatment solution supply operation S20 is started and may be performed until the treatment solution supply operation S20 is completed, or may be started when the treatment solution supply operation S20 is started and performed until the liquid film forming operation S30 is completed.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A method of processing a substrate, the method comprising:
a fluid supply operation of supplying fluid to a lower surface of a rotating substrate;
a treatment solution supply operation of supplying a treatment solution containing a polymer and a volatile solvent to an upper surface of the rotating substrate;
after the treatment solution supply operation, a liquid film forming operation of forming a liquid film of the treatment solution by volatilizing the volatile solvent in the treatment solution and solidifying or curing the treatment solution; and
after the liquid film forming operation, a liquid film removing operation of removing the liquid film of the treatment solution by supplying a removal solution to the substrate,
wherein in the fluid supply operation, the supply of the fluid starts before the liquid film forming operation.

2. The method of claim 1, wherein in the fluid supply operation, the supply of the fluid starts before the treatment solution supply operation.

3. The method of claim 1, wherein in the fluid supply operation, the supply of the fluid continues during the treatment solution supply operation.

4. The method of claim 1, wherein in the fluid supply operation, the supply of the fluid continues during the liquid film forming operation.

5. The method of claim 1, wherein in the fluid supply operation, the supply of the fluid starts to be provided to the lower surface of the substrate before the treatment solution supply operation and continues until the liquid film forming operation is completed.

6. The method of claim 1, wherein the fluid is a wetting solution that wets the lower surface of the substrate.

7. The method of claim 1, wherein the fluid supply operation includes:
a wetting solution supply operation of supplying a wetting solution that wets the lower surface of the substrate to the lower surface of the rotating substrate; and
a gas supply operation of supplying gas forming an airflow to the lower surface of the substrate, and
the wetting solution supply operation and the gas supply operation are performed simultaneously.

8. The method of claim 7, wherein a liquid deposition point at which the wetting solution is deposited on the lower surface of the substrate is farther from a center of the substrate than a gas deposition point at which the gas is deposited on the lower surface of the substrate.

9. The method of claim 6, wherein the wetting solution is supplied toward the lower surface of the substrate to be inclined upward in a direction away from a central axis of the substrate.

10. The method of claim 6, wherein the wetting solution is deionized water.

11. The method of claim 7, wherein the gas is inert gas.

12. The method of claim 1, wherein a temperature of the fluid is room temperature.

13. The method of claim 1, wherein a temperature of the fluid is a temperature higher than room temperature.

14. (canceled)

15. (canceled)

16. (canceled)

17. (canceled)

18. A method of processing a substrate, the method comprising:
a wetting solution supply operation of supplying a wetting solution to a lower surface of a rotating substrate;
a treatment solution supply operation of supplying a treatment solution containing a polymer and a volatile solvent to an upper surface of the rotating substrate;
after the treatment solution supply operation, a liquid film forming operation of forming a liquid film of the treatment solution by volatilizing the volatile solvent in the treatment solution and solidifying or curing the treatment solution; and
after the liquid film forming operation, a liquid film removing operation of removing the liquid film of the treatment solution by supplying a removal solution to the substrate,
in the wetting solution supply operation, the wetting solution starts to be supplied before the treatment solution supply operation and continues to be supplied until the liquid film forming operation is completed, and
the wetting solution is discharged to be inclined upward toward the lower surface of the substrate in a direction away from a central axis of the substrate.

19. The method of claim 18, further comprising:
a gas supply operation of supplying gas to the lower surface of the substrate,
wherein in the gas supply operation, the gas starts to be supplied when the supply of the wetting solution starts, and continues to be supplied until the supply of the wetting solution is completed, and
a liquid deposition point at which the wetting solution is deposited on the lower surface of the substrate is farther from the center of the substrate than a gas deposition point at which the gas is deposited on the lower surface of the substrate.

20. The method of claim 19, wherein the wetting solution is deionized water, and the gas is nitrogen gas.
